(19) United States
(12) Patent Application Publication
(10) Pub. No.: US 2015/0263848 A1
(43) Pub. Date: Sep. 17, 2015

(54) CDR RELOCK WITH CORRECTIVE INTEGRAL REGISTER SEEDING

(71) Applicant: LSI Corporation, San Jose, CA (US)

(72) Inventors: Mohammad S. Mobin, Orefield, PA (US); Weiwei Mao, Macungie, PA (US); Chintan M. Desai, San Jose, CA (US); Ye Liu, San Jose, CA (US)

(73) Assignee: LSI Corporation, San Jose, CA (US)

(21) Appl. No.: 14/257,315

(22) Filed: Apr. 21, 2014

Related U.S. Application Data
(60) Provisional application No. 61/952,491, filed on Mar. 13, 2014.

(51) Int. Cl. H04L 7/00; H03L 7/08

(52) U.S. Cl. CPC H04L 7/0016; H03L 7/0807

(57) ABSTRACT

Described embodiments provide for, in a clock and data recovery (CDR) circuit, detection of loss of acquisition and CDR restarting with corrective integral accumulator register seeding and gearshift restarting. In described embodiments, a mechanism is employed to cause faster loss of lock condition if the CDR circuit directed on an incorrect acquisition trajectory, actual loss of CDR lock is then detected, and CDR acquisition is recovered with corrective integral accumulator seeding.

### CROSS-REFERENCE TO RELATED APPLICATIONS

This application claims the benefit of the filing date of U.S. provisional application No. 61/952,491, filed on Mar. 13, 2014, as attorney docket no. L14-0092, the teachings of which are incorporated herein by reference.

### BACKGROUND

In many data communication applications, Serializer and De-serializer (SerDes) devices facilitate the transmission between two points of parallel data across a serial link. Data at one point is converted from parallel data to serial data and transmitted through a communications channel to the second point where it received and converted from serial data to parallel data.

At high data rates, frequency-dependent signal loss from the communications channel (e.g., the signal path between the two end points of a serial link) as well as signal dispersion and distortion can occur. As such, the communications channel, whether wired, optical, or wireless, acts as a filter and might be modeled in the frequency domain with a transfer function. Correction for frequency dependent losses of the communications channel, and other forms of signal degradation, often requires signal equalization at a receiver of the signal. Equalization through use of one or more equalizers compensates for the signal degradation to improve communication quality.

An eye pattern, also known as an eye diagram (the “eye), represents a digital data signal from a receiver that is repetitively sampled and applied to the vertical input (axis), while the horizontal input (axis) represents time as a function of the data rate. The eye diagram allows for evaluation of the combined effects of channel noise and inter-symbol interference on the performance of a baseband pulse-transmission system, and the input data eye is the synchronized superposition of all possible realizations of the signal of interest viewed within a particular signaling interval (referred to generally as the EYE).

A clock and data recovery (CDR) circuit detects timing of the input data stream and uses such detected timing to set correct frequency and phase of a local clock from which the sampling clock for data sampling is derived. As employed herein, “placing” a sampler (latch) in a data stream requires setting a voltage threshold and clocking phase of the sampler to detect a predetermined point in a data eye. Clocking the data sampler with a clock signal with known frequency and phase derived with respect to the detected symbol timing of data allows for clock recovery of symbols within the data stream generating the data eye.

CDR circuits form a critical part of the receiver in a SerDes device. The objective of the CDR circuit is to track the phase of a sampling clock based on some criterion, such as minimized mean-squared-error (MMSE). To track the phase of a sampling clock based on a given criterion, the CDR circuit generates (timing) error samples with respect to the data sampling clock, and adaptively sets the local clock phase used to derive the data sampling clock so as to minimize the timing error with respect to the criterion between successive sampling events. The CDR circuit desirably operates so as to achieve very low target bit-error-ratio (BER) (usually, on the order of le-12 or le-15).

A classical CDR consists of a phase detector to determine the early/late indication of the sampling clock with respect to data transition. The early/late indication in a reasonably low relative ppm (part per million) difference between the recovering clock and incoming data rate is sufficient for the CDR circuit to lock its frequency to that of the incoming signal (CDR lock) through its proportional path and integral path a loop filter of the CDR circuit.

A classical CDR circuit employs proper loop filter gain gearshift to acquire CDR lock with a large acquisition bandwidth and eventually tightens the CDR loop filter BW with gear shifting down the proportional path and integral path gain for reduced jitter generation at steady state operation. The CDR acquisition at high ppm, unfavorable sampling phase, and less than perfect integral non-linearity (INL) and differential non-linearity (DNL) of a phase interpolator of the CDR circuit may drive CDR in wrong direction (i.e., away from the frequency of the incoming data) causing a CDR lock failure.

CDR acquisition in presence of large ppm offset between the local clock and input data can result in loss of CDR acquisition. In addition to ppm offset, wrong phase sampling over the input EYE can also result in incorrect bang-bang (BB) phase update (for a phase detector implemented as a bang-bang phase detector) in a CDR integral path register and can contribute to loss of CDR acquisition by incorrect integral accumulator register buildup. Also, excessive increase/decrease of INL and DNL in clock phase interpolators aggravates the CDR acquisition.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

In one embodiment, the present invention provides for locking a local clock to an input data stream by a clock and data recovery (CDR) circuit during an acquisition process. The CDR circuit during an acquisition process initializes a proportional gain path and an integral gain path to respective initial gain values; performs the acquisition process; and monitors a value of an integral accumulator of the integral gain path for saturation during the acquisition process. If the value of the integral accumulator reaches saturation, logic circuitry: (i) terminates the acquisition process; (ii) resets the gain values of the proportional gain path and the integral gain path; (iii) programs the integral accumulator with a seed value; and (iv) restarts the acquisition process.

### BRIEF DESCRIPTION OF THE DRAWINGS

Other aspects, features, and advantages will become more fully apparent from the following detailed description, the appended claims, and the accompanying drawings in which like reference numerals identify similar or identical elements.

FIG. 1 shows a clock and data recovery (CDR) circuit employing an exemplary embodiment;

FIG. 2 shows an exemplary embodiment of a method for CDR relock with corrective integral register seeding as employed by the CDR of FIG. 1;

FIG. 3 shows integral and proportional gear shifting signals for the CDR of FIG. 1;

FIG. 4 illustrates a worst case spread spectrum clocking part per million offset applied at the beginning of simulation of a up;

FIG. 5. illustrates a bad input EYE sampling phase at the CDR circuit input;

FIG. 6 shows CDR acquisition employing an exemplary embodiment in presence of SSC; and

FIG. 7 shows CDR acquisition employing an exemplary embodiment in presence of fixed ppm offset.

### DETAILED DESCRIPTION

Described embodiments provide for, in a clock and data recovery (CDR) circuit, detection of loss of acquisition and CDR restarting with corrective integral accumulator register seeding and gearshift restarting. In described embodiments, a mechanism is employed to cause faster loss of lock condition if the CDR circuit directed on an incorrect acquisition trajectory, actual loss of CDR lock is then detected, and CDR acquisition is recovered with corrective integral accumulator seeding.

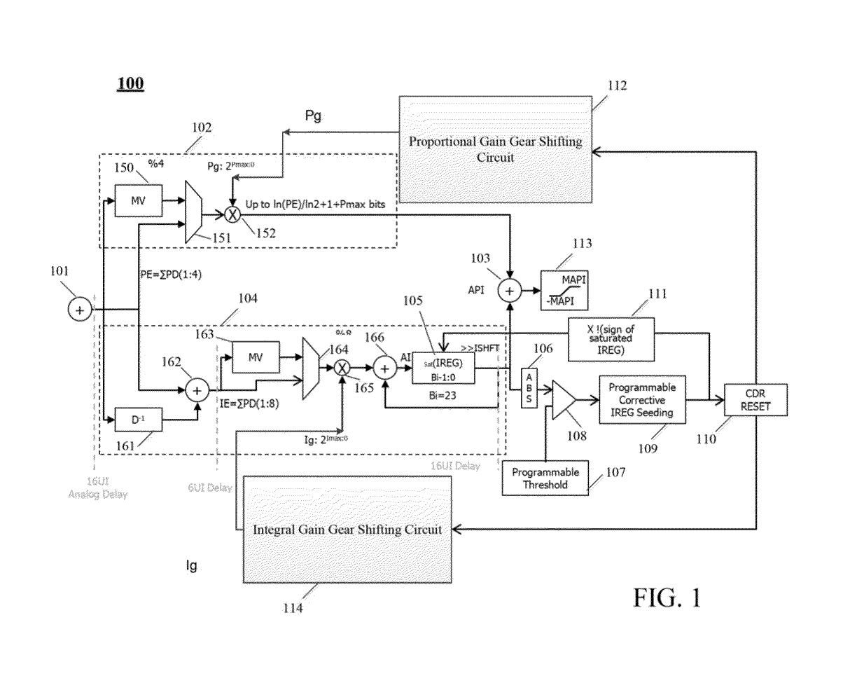

FIG. 1 shows a portion of a clock and data recovery (CDR) circuit 100 employing an exemplary embodiment. FIG. 1 shows the integral and proportional gain control for the CDR circuit 100, and components such as the oscillator (e.g., local clock), phase detector, and so forth well known in the art of clock and data recovery are omitted for clarity in the description. CDR circuit 100 receives at its input node 101 samples from the phase detector and sampler representing phase update request data, which is provided to proportional gain path 102 and integral gain path 104. Proportional gain path 102 and integral gain path 104 provide gain increment or decrement signals, which are combined in adder 103, to control and adjust phase of the local clock. At start-up, each of proportional gain path 102 and integral gain path 104 have gear shifting applied by proportional gain gear shifting circuit 112 and integral gain gear shifting circuit 114, respectively, which accelerates the process of frequency lock as described subsequently.

Integral gain path 104 includes an integral accumulator register 105, which accumulates and stores the current value of integral gain control (IREG) provided to adder 103. In addition, the absolute value of IREG is formed in circuit 106, and compared with a programmable threshold, from register 107, in comparator 108. The programmable threshold in register 107 is related to the saturation value of IREG, discussed subsequently.

If the output signal of comparator 108 indicates that the threshold is met, then programmable corrective IREG seeding circuit 109 i) detects saturation, ii) generates a new seed value to load into integral accumulator register 105, and iii) triggers CDR reset 110. CDR reset 110, in turn, re-initializes proportional gain gear shifting circuit 112 and integral gain gear shifting circuit 114 to initial (predetermined) acquisition values.

As shown in the FIG. 1, proportional gain path 102 comprises majority vote (MV) 150 multiplexer 151, and multiplier 152. Integral gain path 104 comprises delay 161, adder 162, majority vote (MV) 163 multiplexer 164, and multiplier 165. Integral gain path 104 further comprises an integrator formed of adder 166 and integral accumulator register 105.

Proportional gain path 102 and integral gain path 104 operate differently during initial acquisition (or “start-up”) and in steady state operation. The CDR local clock (e.g., VCO) utilizes two control loops, proportional and integral, which allow for more precise tracking of the incoming data clock rate as its frequency deviates from the nominal rate. “Gear shifting” is used during start up to reduce the time to lock the CDR circuit to the incoming signal's data clock. Gear shifting provides a higher multiplication coefficient for the proportional and integral control loops of the CDR circuit's local reference clock generator, such as a VCO, in the initial phase of locking to a serial data stream, providing for wider bandwidth, in order to reduce time-to-lock.

A phase update request (PD) from the CDR phase detector (typically a bang-bang phase detector) might optionally utilize, (by selection with MUX 151) either a majority vote (e.g., from MV 150) or simple average of phase update requests to generate a proportional error (PE), where multiple phase update requests are converted to a single up, down, or no phase update. The resulting phase update might also be processed by proportional gain gear shifting circuit 112 and multiplier 152. This processing by proportional gain gear shifting circuit 112 and multiplier 152 might have a higher multiplication coefficient in the initial phase of locking to a serial data stream. After start-up, over the course of time, the proportional gain Pg of proportional gain gear shifting circuit 112 and multiplier 152 is reduced, narrowing the CDR loop bandwidth, and, thus, reducing self-jitter characteristic of a non-linear bang-bang phase detector based implementation of CDR circuit 100.

The final phase update request from the gear shifting multiplier 152 is applied as a proportional control word to the VCO (not shown in FIG. 1) via adder 103. Proportional control has a character of pulse width modulation control. Each time proportional control is applied for a limited duration of time, the proportional control causes a temporary change in frequency of CDR circuit 100.

Integral control, unlike proportional control, changes for an extended duration of time. Integral control in a CDR drives the error value to zero while maintaining a control signal (at steady state, the contribution to adder 103 approaches zero). A phase update request (PD) from the CDR phase detector might optionally utilize, (by selection with MUX 164) either a majority vote (e.g., from MV 163) or simple average of phase update requests to generate an integral error (IE). Integration of integral error (IE) is performed accumulated feedback via adder 166 and integral accumulator register 105. Again, as described previously, the integral control is modified at startup through action of gear shifting control. Gear shifting integral control Ig is applied via integral gain gear shifting circuit 114 and multiplier 165.

Typical CDR circuits, during acquisition, initially set the gain of the proportional gain path to a relatively high value. In practice, this large gain allows the CDR to attempt to lock to an incoming data clock that differs from the local clock phase/frequency by a relatively large amount. However, while the error signal generated during this period will gradually push the local clock frequency to either lock (successful lock to data clock frequency) or to false lock (integral gain path to the rail, i.e., CDR lock failure), the time to determine this state might be relatively long. In contrast, in accordance with exemplary embodiments, to decrease time to determine lock or false lock, the gain of the proportional gain path is set to a relatively low value. The error signal generated during this period rapidly pushes the local clock frequency to either lock (successful lock to data clock frequency) or to false lock, where the integral gain path is pushed to its rails (i.e., CDR lock failure), indicated by the value in the integral accumulator register going to a saturation value.

The i) time instant to start acquisition to ii) the time instant that the integral accumulator register reaches saturation is monitored. The time period between start and success/failure can be related to the distance in phase/frequency the local clock is from the data clock, and this relation can be employed to estimate the correct value for the integral gain path to push the local clock toward lock faster, which, in turn, can be related to a “seed value” or initial value loaded into the integral accumulator register to start the acquisition process. Seed values related to time to CDR lock failure might be predetermined for an implementation and stored, for example, in a table. For example, if the integral accumulator register saturates in 1 msec, then there is an associated integral accumulator register seed value for this time to CDR lock failure for a given clock rate. Also, saturation indicates that the CDR is adjusting the local clock in the opposite direction in phase/frequency to achieve lock, so the sign of the seed is inverted with respect to the current integral accumulator register value to change this direction.

In accordance with exemplary embodiments during an iterative process to acquire CDR lock, if the time to CDR lock failure is measured, then for a next iteration the seed loaded into the integral accumulator register is of larger value, and opposite sign. Preferred embodiments might employ a value of twice the previous value.

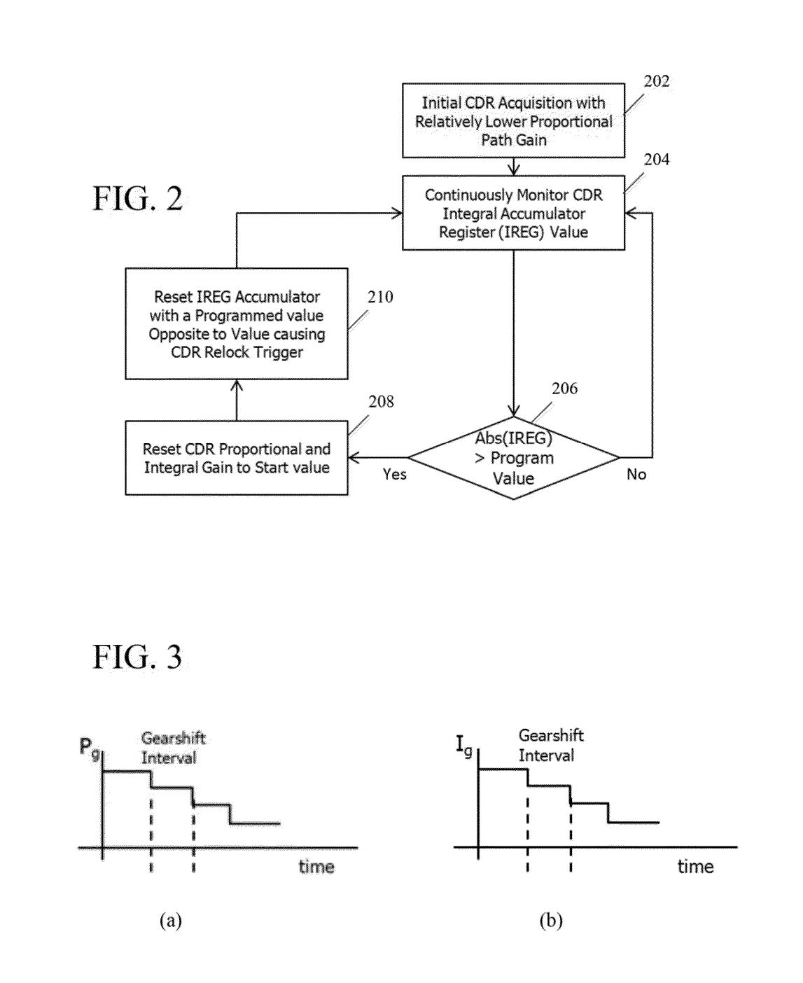

Operation of the elements of FIG. 1 is now described with respect to FIGS. 2 and 3.

FIG. 2 shows an exemplary embodiment of a method for CDR relock with corrective integral register seeding as employed by the CDR of FIG. 1. At step 202, during initial CDR circuit acquisition, the proportional path gain is set to a relatively low value. At step 204, the integral accumulator register value (IREG) is monitored. At step 206, a test determines if the integral accumulator register value IREG reaches a threshold indicating saturation (e.g., absolute value of IREG is greater than a programmable value). If the test of step 206 determines that the integral accumulator register value IREG has not reached a threshold, the method returns to step 204.

If the test of step 206 determines that the integral accumulator register value IREG has reached a threshold, the method advances to step 208. At step 208, the CDR proportional and integral gain values are reset to their initial values. At step 210, the integral accumulator register value IREG is reset with a programmed value opposite to the value causing CDR relock to trigger. From step 210, the method returns to step 204.

FIG. 3 shows integral and proportional gear shifting signals for the CDR of FIG. 1. Gear shifting circuit 112 for the proportional gain path of FIG. 1 is shown in FIG. 3(a), where after initialization, the gear shifting operation steps down the proportional gain value in increments for each gearshift interval. Similarly, Gear shifting circuit 114 for the integral gain path of FIG. 1 is shown in FIG. 3(b), where after initialization, the gear shifting operation steps down the integral gain value in increments for each gearshift interval.

For the embodiments of FIGS. 1 and 2, the operation can be summarized as follows. The CDR proportional path bandwidth (BW) is reduced compared to approaches used in typical CDR circuits, where initial BW is large for large frequency pull in, and eventually the BW is reduced for low self-jitter generation and smooth tracking. With low initial proportional gain and, hence, low startup BW, the CDR circuit has a 50% probability to lock or not lock based on initial CDR sampling phase on the input EYE, the input PPM offset, and severity of the interpolator linearity.

The CDR lock status is detected by monitoring the integral accumulator. If the CDR locks properly, its integral accumulator will have non-saturated value (since the proportional path gain is low and will track easily, inhibiting saturation of the integral accumulator register). If the CDR circuit does not lock, the CDR circuit drives the integral accumulator register in an opposite direction, creating a large locally generated opposite ppm offset. The CDR status of out of lock is detected by monitoring the integral accumulate or register value saturation. If the integral accumulator register saturates in one direction, then a corrective integral accumulator register seeding is performed in the opposite direction with a programmable preset value. The CDR circuit is then is restarted by initializing the proportional and integral path gains to their starting value.

A CDR circuit employing one or more embodiments of the present invention might provide the following advantages. Where CDR acquisition occurs in the presence of large ppm offset between the local clock and input data, the potential for CDR lock failure is reduced or eliminated. For example, in Serializer/Deserializer (SerDes) applications where CDR acquisition in the presence of large ppm offset between the local clock and input data is common, such as storage and PCIe SerDes, the potential for loss of CDR acquisition is reduced or eliminated. In addition, wrong phase sampling over the input EYE is reduced or eliminated, providing correct bang-bang (BB) phase update (for a phase detector implemented as a bang-bang phase detector) in a CDR integral path register, and reducing or eliminating excessive integral accumulator register buildup.

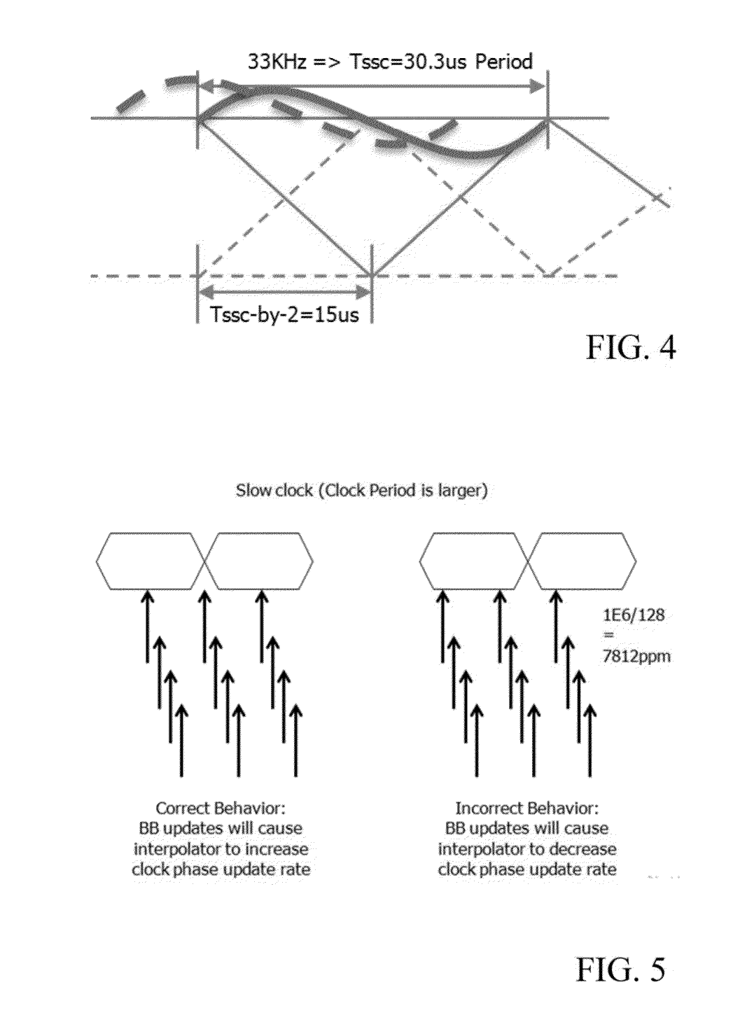

Simulation results employing the current invention illustrate operation and performance advantages. In simulations, the worst case spread spectrum clocking PPM offset is applied at the beginning of the simulation, as shown in FIG. 4.

The sampling phase on EYE is another contributor in CDR lock failure. It is important to consider the CDR loop latency to account for the bad CDR input EYE phase sampling since CDR will not see the EYE until the implementation delays. FIG. 5 illustrates a bad input EYE sampling phase at the CDR circuit input.

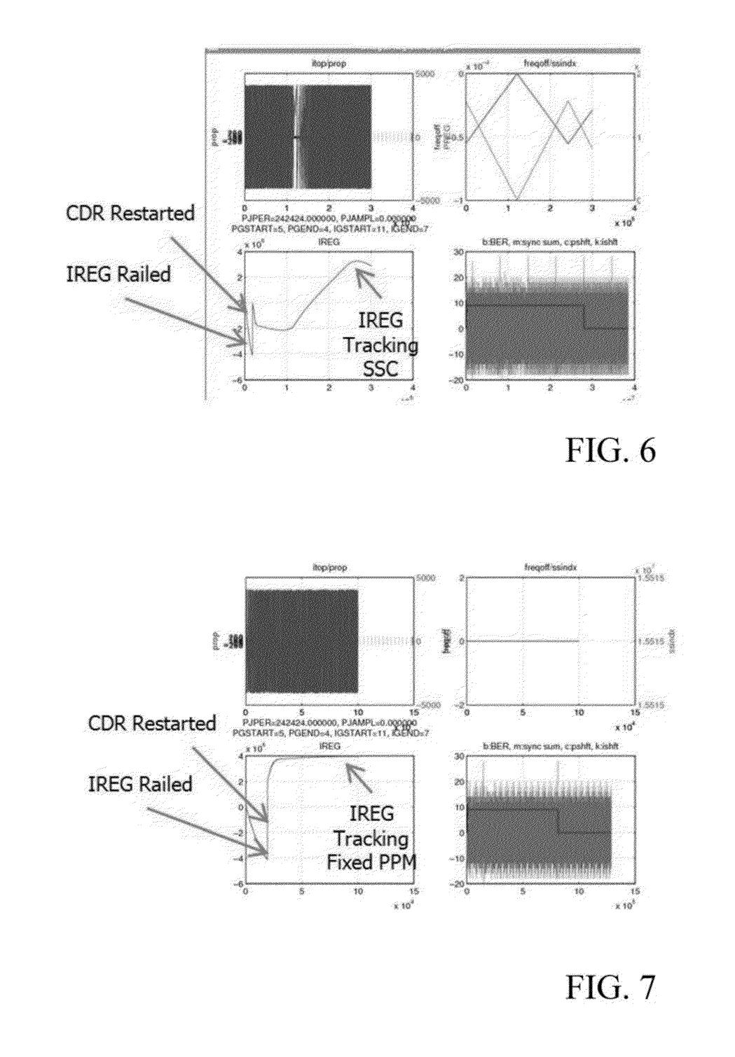

In above conditions when CDR lock fail happens the integral accumulator register rails in opposite polarity compared to actual relative PPM difference between the local clock and the input data rate. Two examples are provided: FIGS. 6 and 7 illustrate that, in presence of SSC and PPM offset, the CDR lock fails, and CDR relock with corrective integral accumulator register seeding recovers the CDR in correct state. FIG. 6 shows CDR acquisition employing an exemplary embodiment in presence of SSC. FIG. 7 shows CDR acquisition employing an exemplary embodiment in presence of fixed+7000 ppm offset.

Reference herein to “one embodiment” or “an embodiment” means that a particular feature, structure, or characteristic described in connection with the embodiment can be included in at least one embodiment. The appearances of the phrase “in one embodiment” in various places in the specification are not necessarily all referring to the same embodiment, nor are separate or alternative embodiments necessarily mutually exclusive of other embodiments. The same applies to the term “implementation.”

As used in this application, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion.

Additionally, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

Moreover, the terms “system,” “component,” “module,” “interface,”, “model” or the like are generally intended to refer to a computer-related entity, either hardware, a combination of hardware and software, software, or software in execution. For example, a component may be, but is not limited to being, a process running on a processor, a processor, an object, an executable, a thread of execution, a program, and/or a computer. By way of illustration, both an application running on a controller and the controller can be a component. One or more components may reside within a process and/or thread of execution and a component may be localized on one computer and/or distributed between two or more computers.

While the exemplary embodiments of the present invention have been described with respect to processes of circuits, including possible implementation as a single integrated circuit, a multi-chip module, a single card, or a multi-card circuit pack, the present invention is not so limited. As would be apparent to one skilled in the art, various functions of circuit elements may also be implemented as processing blocks in a software program. Such software may be employed in, for example, a digital signal processor, micro-controller, or general purpose computer.

The present invention can be embodied in the form of methods and apparatuses for practicing those methods. The present invention can also be embodied in the form of program code embodied in tangible media, such as magnetic recording media, optical recording media, solid state memory, floppy diskettes, CD-ROMs, hard drives, or any other machine-readable storage medium, wherein, when the program code is loaded into and executed by a machine, such as a computer, the machine becomes an apparatus for practicing the invention. The present invention can also be embodied in the form of program code, for example, whether stored in a storage medium, loaded into and/or executed by a machine, or transmitted over some transmission medium or carrier, such as over electrical wiring or cabling, through fiber optics, or via electromagnetic radiation, wherein, when the program code is loaded into and executed by a machine, such as a computer, the machine becomes an apparatus for practicing the invention. When implemented on a general-purpose processor, the program code segments combine with the processor to provide a unique device that operates analogously to specific logic circuits. The present invention can also be embodied in the form of a bitstream or other sequence of signal values electrically or optically transmitted through a medium, stored magnetic-field variations in a magnetic recording medium, etc., generated using a method and/or an apparatus of the present invention.

Unless explicitly stated otherwise, each numerical value and range should be interpreted as being approximate as if the word “about” or “approximately” preceded the value of the value or range.

It should be understood that the steps of the exemplary methods set forth herein are not necessarily required to be performed in the order described, and the order of the steps of such methods should be understood to be merely exemplary. Likewise, additional steps may be included in such methods, and certain steps may be omitted or combined, in methods consistent with various embodiments of the present invention.

As used herein in reference to an element and a standard, the term “compatible” means that the element communicates with other elements in a manner wholly or partially specified by the standard, and would be recognized by other elements as sufficiently capable of communicating with the other elements in the manner specified by the standard. The compatible element does not need to operate internally in a manner specified by the standard.

Through the whole document, the term “connected to” or “coupled to” that is used to designate a connection or coupling of one element to another element includes both a case that an element is “directly connected or coupled to” another element and a case that an element is “electronically connected or coupled to” another element via still another element.

Further, the term “comprises or includes” and/or “comprising or including” used in the document means that one or more other components, steps, operation and/or existence or addition of elements are not excluded in addition to the described components, steps, operation and/or elements.

Signals and corresponding nodes or ports may be referred to by the same name and are interchangeable for purposes here.

No claim element herein is to be construed under the provisions of 35 U.S.C. §112, sixth paragraph, unless the element is expressly recited using the phrase “means for” or “step for.”

It is understood that various changes in the details, materials, and arrangements of the parts which have been described and illustrated in order to explain the nature of this invention may be made by those skilled in the art without departing from the scope of the embodiments of the invention as encompassed in the following claims.

We claim:

1. A method of locking a local clock to an input data stream by a clock and data recovery (CDR) circuit during an acquisition process, the method comprising of:
initializing a proportional gain path and an integral gain path to respective initial gain values;
performing the acquisition process;
monitoring a value of an integral accumulator of the integral gain path for saturation during the acquisition process; and
if the value of the integral accumulator reaches saturation:
terminating the acquisition process;
resetting the gain values of the proportional gain path and the integral gain path;
programming the integral accumulator with a seed value; and
restarting the acquisition process.

2. The method of claim 1, comprising repeating the method until the local clock locks to the input data stream.

3. The method of claim 1, wherein, for the programming the integral accumulator with a seed value, the method programs with a current seed value having opposite sign to the sign of the current value of the integral accumulator.

4. The method of claim 3, comprising monitoring a time period for the value of the integral accumulator to reach saturation, indicating CDR lock failure, wherein a length of the time period relates to a previously used seed value for the integral accumulator resulting in the CDR lock failure.

5. The method of claim 4, wherein absolute value of the current seed value is greater than the absolute value of the previously used seed value.

6. The method of claim 3, wherein the programming the integral accumulator with a seed value includes selecting the seed value from a table based on a time period for the value of the integral accumulator to reach saturation.

7. The method of claim 1, wherein the resetting the gain values of the proportional gain path and the integral gain path initializes corresponding coefficients of a proportional gain gear shifting circuit and an integral gain gear shifting circuit in the proportional gain path and the integral gain path, respectively.

8. Apparatus for locking a local clock to an input data stream by a clock and data recovery (CDR) circuit during an acquisition process, the apparatus comprising:
a proportional gain path and an integral gain path set to respective initial gain values, the integral gain path including an integral accumulator; and
a logic circuit including a monitoring circuit to detect whether a value of the integral accumulator of the integral gain path reaches saturation during the acquisition process;
wherein, while the CDR circuit performs the acquisition process:
if the value of the integral accumulator reaches saturation, the logic circuit:
terminates the acquisition process;
resets the gain values of the proportional gain path and the integral gain path;
programs the integral accumulator with a seed value; and
restarts the acquisition process.

9. The apparatus of claim 8, wherein, when the integral accumulator is programmed with a seed value, the logic circuit programs with a current seed value having opposite sign to the sign of the current value of the integral accumulator.

10. The apparatus of claim 9, wherein the monitoring circuit monitors a time period for the value of the integral accumulator to reach saturation, indicating CDR lock failure, wherein a length of the time period relates to a previously used seed value for the integral accumulator resulting in the CDR lock failure.

11. The apparatus of claim 10, wherein absolute value of the current seed value is greater than the absolute value of the previously used seed value.

12. The apparatus of claim 9, wherein the logic circuit programs the integral accumulator with the seed value from a table based on a time period for the value of the integral accumulator to reach saturation.

13. The method of claim 8, wherein the logic circuit resets the gain values of the proportional gain path, and the logic circuit initializes corresponding coefficients of a proportional gain gear shifting circuit and an integral gain gear shifting circuit in the proportional gain path and the integral gain path, respectively.

14. The invention of claim 8, wherein the apparatus is embodied in a Serializer/Deserializer (SerDes) device.

15. The invention of claim 8, wherein the apparatus is embodied in an integrated circuit.

16. A non-transitory machine-readable storage medium, having encoded thereon program code, wherein, when the program code is executed by a machine, the machine implements a method for locking a local clock to an input data stream by a clock and data recovery (CDR) circuit during an acquisition process, comprising the steps of:
initializing a proportional gain path and an integral gain path to respective initial gain values;
performing the acquisition process;
monitoring a value of an integral accumulator of the integral gain path for saturation during the acquisition process; and
if the value of the integral accumulator reaches saturation:
terminating the acquisition process;
resetting the gain values of the proportional gain path and the integral gain path;
programming the integral accumulator with a seed value; and
restarting the acquisition process.

17. The method of claim 16, comprising repeating the method until the local clock locks to the input data stream.
